(19) United States
(12) Patent Application Publication
(10) Pub. No.: US 2014/0109956 A1
(43) Pub. Date: Apr. 24, 2014

(54) High Performance Backsheet for Photovoltaic Applications and Method for Manufacturing the Same

(71) Applicant: Madico, Inc., Woburn, MA (US)

(72) Inventors: Marina Temchenko, Swampscott, MA (US); David W. Avison, Townsend, MA (US); Bradley J. Forest, Rutland, MA (US)

(73) Assignee: Madico, Inc., Woburn, MA (US)

(21) Appl. No.: 14/143,415

(22) Filed: Dec. 30, 2013

Related U.S. Application Data
(63) Continuation of application No. 12/977,893, filed on Dec. 23, 2010.
(60) Provisional application No. 61/353,264, filed on Jun. 10, 2010.
(60) Provisional application No. 61/289,646, filed on Dec. 23, 2009.

(51) Int. Cl. H01L 31/048

(52) U.S. Cl. CPC H01L 31/0487
USPC 136/251; 136/259

(57) ABSTRACT

The present invention provides a high performance backsheet (alternatively referred to backing sheet) for photovoltaic applications and methods for manufacture of the same. The high performance backsheet includes a compounded thermoplastic polyolefin or compounded ethylene vinyl acetate (“EVA”). The compounded thermoplastic polyolefin or EVA may be used by itself as one layer, or incorporated into a layer, or as a layer in multilayer laminate. The compounded thermoplastic polyolefin or EVA is useful in eliminating the necessity of using polyester in the backing sheet.

### CROSS-REFERENCE TO RELATED APPLICATIONS

This application is a continuation of U.S. application Ser. No. 12/977,893 filed Dec. 23, 2010, entitled “HIGH PERFORMANCE BACKSHEET FOR PHOTOVOLTAIC APPLICATIONS AND METHOD FOR MANUFACTURING THE SAME” published as U.S. 2011/0146762 now pending, which claims the benefit of U.S. Provisional Application No. 61/289,646 filed Dec. 23, 2009, and U.S. Provisional Application No. 61/353,264 filed Jun. 10, 2010.

Each patent application identified above is incorporated herein by reference in its entirety to provide continuity of disclosure.

### BACKGROUND OF THE INVENTION

1. Field of the Invention

The present invention relates to photovoltaic modules. More specifically the present invention relates to the protective backing sheets and encapsulants of photovoltaic modules.

2. Description of Related Art

Solar energy utilized by photovoltaic modules is among the most promising alternatives to the fossil fuel that is being exhausted this century. However, production and installation of the photovoltaic modules remains an expensive process. Typical photovoltaic modules consist of glass or flexible transparent front sheet, solar cells, encapsulant, protective backing sheet, a protective seal which covers the edges of the module, and a perimeter frame made of aluminum which covers the seal. As illustrated in FIG. 1, a front sheet 10, backing sheet 20 and encapsulant 30 and 30′ are designed to protect array of cells 40 from weather agents, humidity, mechanical loads and impacts. Also, they provide electrical isolation for people's safety and loss of current. Protective backing sheets 20 are intended to improve the lifecycle and efficiency of the photovoltaic modules, thus reducing the cost per watt of the photovoltaic electricity. While the front sheet 10 and encapsulant 30 and 30′ must be transparent for high light transmission, the backing sheet typically has high opacity for aesthetic purposes and high reflectivity for functional purposes. Light and thin solar cell modules are desirable for a number of reasons including weight reduction, especially for architectural (building integrated PV) and space applications, as well as military applications (incorporated into the soldier outfit, etc). Additionally light and thin modules contribute to cost reduction. Also reduction in quantity of consumed materials makes the technology “greener,” thus saving more natural resources.

One means to manufacture light and thin solar cells is to incorporate light and thin backing sheets. The backside covering material, however, must also have high moisture resistance to prevent permeation of moisture vapor and water, which can cause corrosion of underlying parts such as the photovoltaic element, wire, and electrodes, and damage solar cells. In addition, backing sheets should provide electrical isolation, mechanical protection, UV protection, adherence to the encapsulant and ability to attach output leads.

PV modules are frequently used in “hostile” chemical environments . . . including agricultural settings rich in ammonia-generating bio-waste. Most commercial PV modules utilize polymeric backsheets for environmental protection from moisture ingress, UV degradation, and physical damage, and to provide electrical insulation. Virtually all polymeric backsheets on the market today utilize polyester (more specifically, polyethylene terephthalate) as a key component in their construction for its excellent dielectric properties and mechanical strength.

Polyester films, especially conventional polyethylene terephthalate films are, however, susceptible to hydrolytic degradation (as well as other environmental degradation mechanisms). Such hydrolytic degradation is accelerated under high pH (basic) and low pH (acidic) conditions. High pH exposure conditions may result, for example, from use in an agricultural setting. A low pH exposure condition may result from, for example, exposure to “acid rain” or, even in the absence of extreme environmental conditions, gradual degradation of the internal components of the PV module (e.g., EVA encapsulant).

As the polyester film component chemically degrades, both its di-electric efficacy and mechanical properties also degrade, thereby reducing the effectiveness of the composite backsheet, and increasing risk of PV module failure. Polyester film suppliers have demonstrated the ability to improve upon hydrolytic stability, as well as other potential degradation mechanisms, by modification of the base polymer (e.g., PEN, PBT), polymerization process or subsequent purification process to minimize oligomer level, or compounding with the appropriate additives. Such modifications have proven to be effective but come at substantial expense.

It would be desirable to find a more cost efficient means to improve upon hydrolytic stability, as well as other potential degradation mechanisms of solar cells backing sheets at a lower cost than is currently available. It would be desirable to find a more cost efficient material that performs the function of polyester in that minimize the negative characteristics of polyester.

### SUMMARY OF THE INVENTION

The present invention provides a high performance backsheet (alternatively referred to backing sheet) for photovoltaic applications and method for manufacture of same. The high performance backsheet includes a compounded thermoplastic polyolefin or compounded ethylene vinyl acetate (“EVA”). The compounded thermoplastic polyolefin or EVA may be used by itself as one layer, or incorporated into a layer, or as a layer in multilayer laminate. The compounded thermoplastic polyolefin or EVA is useful in eliminating the necessity of using polyester in the backing sheet.

Compounding refers to the incorporation of additives into the base polymer system. These additives can serve a variety of functions, either alone or in combination with other additives. For example, anti-oxidants Cyanox 2777 (Cytec) minimize thermal degradation of the polymeric chain at the elevated temperatures used for the film extrusion process. Organic UV absorbers, and UV-blocking inorganic pigments such as TiO₂, enhance the weatherability of the backsheet in end use application, and also enhance the thermal oxidative stability even in the absence of conventional anti-oxidants. Enhancement of module performance is accomplished by including additive that increases the photo-reflectance and/or photo-luminescence of the backsheet and heat-dissipation (via use of phase-change materials and thermally conductive inorganic pigments).

In one embodiment, a backsheet that does not require a polyester layer is provided. In another embodiment the backsheet is a laminate and the polyester layer of a traditional laminate is replaced with compounded EVA. In a preferred embodiment, the EVA is compounded with a combination of anti-oxidants and light stabilizers.

### BRIEF DESCRIPTION OF THE DRAWINGS

For a better understanding of the present invention, reference may be made to the accompanying drawings.

FIG. 1 represents an expanded view of the components of a typical photovoltaic module.

FIG. 2 represents one embodiment of the typical backing sheet.

FIG. 3 is a graph illustrating the results of tests on Example 1.

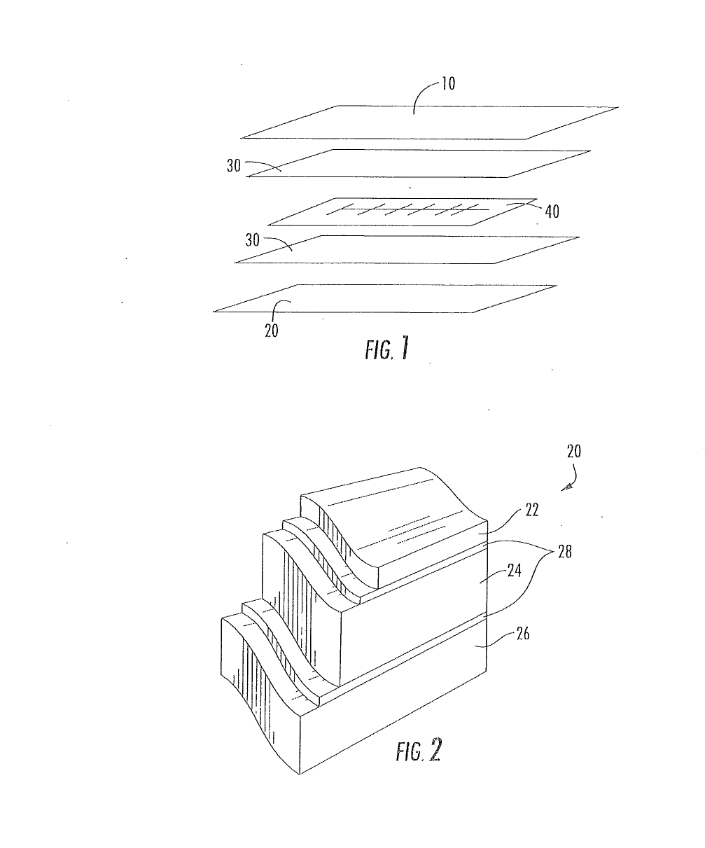

### DETAILED DESCRIPTION

A backsheet for a photovoltaic module offers the same performance of traditional backsheets or better at a reduced cost is provided. The new backsheet incorporates one or more layers of compounded thermoplastic polyolefin, or compounded ethylene vinyl acetate, or a combination of compounded polymer layers.

Polyolefins represent an extremely versatile and low-cost class of polymeric materials that lend themselves to a broad range of applications. As used herein, polyolefins means a polymer produced from a simple olefin (also called an alkene with the general formula CₙH₂ₙ) as a monomer and include, but are not limited to, polyethylene, polypropylene, cyclic olefinic copolymers (COC), EPDM, TPX (polymethyl pentene), olefin co-polymers, olefin-acrylic copolymers, olefin-vinyl copolymers, and numerous others. The polyolefin used can be a single homopolymeric or copolymeric polyolefin, or a combination of two or more polyolefins Polyolefins are inherently resistant to hydrolysis and degradation by other means of chemical attack, and can be readily compounded to minimize degradation by other mechanisms (UV- and oxidative-degradation, for example). Polyolefins are not typically used in backsheets because they easily degrade upon exposure to higher temperatures and UV light.

Ethylene vinyl (“EVA”) acetate has very good dielectric properties and excellent moisture resistance. Additionally, it is not as susceptible to hydrolysis as polyester. However, uncompounded EVA is not thermally stable and releases acidic acid when exposed to heat. Acetic acid negatively affects the tensile strength of the backsheet. Accordingly, it has been discovered that compounding EVA can improve the stability of the EVA and minimize UV and thermal degradation.

Compounding, as used herein refers to the incorporation of additives into the base polymer system. The specific additive used will depend on the desired property of either the end product or a property helpful to the manufacture. Examples of additive that may be used include but not limited to exterior-grade TiO₂ (or BaSO₄, CaCO₃), UVAs, HALs, light stabilizers, AOs, thermally conductive/electrically resistive pigments, optical brighteners/photo-luminescent agents, visible light pigments, IR reflecting pigments, and others. The additives can be used alone or in combination with other additives.

The backsheet can be comprised of just a single sheet of compounded polymer or alternatively a multiple layer structure (laminate) where each layer has different properties depending upon the price requirements and performance requirements of the backsheet. For example, in one embodiment, the backsheet is a laminate with an inner layer of a compounded thermoplastic polyolefin adhered to an outer weatherable layer. For another example, the layer of compounded thermoplastic polyolefin may be the middle layer of a three layer laminate that includes an outer weatherable layer and inner layer that functions to provide adhesion to the cell or encapsulant and/or function to provide reflectance enhancement of the backsheet. These additional layers may be compounded polyolefin or EVA or some other material typically used in backsheet construction.

In the typical photovoltaic module, the layer of a backsheet laminate which is adjacent to the solar cells should be more thermally stable and flame resistant. The internal layer must be very dielectric. This can be accomplished as a two or three layer laminate of separate layers or it can be one layer just combining all of the properties in one layer. That is the polyolefin or EVA can be compounded to have all the required properties in one sheet or separate layers compounded differently. For example, the backing sheet can have compounded EVA and a layer of compounded polypropylene to add a mechanical rigidity to the whole backsheet if needed. The compounded thermoplastic polyolefin or EVA is useful in eliminating the necessity of using polyester in the backing sheet.

The backing sheet is preferably manufactured by extrusion or co-extrusion of appropriately compounded polyolefin-based or EVA based film. Typically, the compounding process entails homogeneous distribution of additives throughout the polymer matrix to modify the properties for either subsequent processing or end-use applications. Polyolefinic resins are typically compounded by heating well above the melting point in a compound, or mixer, extruder; this is an extruder in which the function of the mixing section is emphasized. This approach offers the benefits of reducing risk of contamination, use of inert atmospheres to ensure thermo-oxidative stability, and continuous compounding/blending processes. When combining with an outer weatherable layer or layers, subsequent in-line coatings of the film with the additional layers are performed. The manufacturing process can and preferably is executed without the use of excessive solvents; this type of manufacture is facilitated by use of melt extrusion/co-extrusion technology for the substrate (the compounded polyolefin layer), followed by in-line solventless coating of auxiliary layers (e.g., outer weatherable layer, inner adhesion promoting and/or photo-reflective layer).

In a preferred embodiment, the outer weatherable layer is coated as a solventless radiation- or dual-mechanism (radiation & thermal) cure, although other methods may be used.

When the backsheet is a laminate, the additional layer or layers can be chosen from polymer films and materials known in the art. In one embodiment the laminate comprises (a) a first outer layer of weatherable film; (b) at least one mid-layer; and (c) a second outer layer (alternatively referred to as an inner layer). When used in a photovoltaic module, the first outer layer of the laminate is exposed to the environment, and the inner layer is exposed to or faces the solar cells and solar radiation. The inner layer can be made of any material, but is typically made of one or more polymers.

Alternatively, the backing sheet can be one single layer in which all of the desired properties are combined in one layer. The one layer can be compounded polyolefin, EVA or combination of both.

The outer weatherable film may be chosen from a variety of weatherable polymers such as fluoropolymers (e.g. Tedlar), acrylics, polysiloxanes, urethanes, and alkyds or a compounded polyolefin or EVA. One preferred weatherable layer is an organic solvent soluble, crosslinkable amorphous fluoropolymers. The fluoropolymer may be a fluorocopolymer of chlorotrifluoroethylene (CTFE) and one or more alkyl vinyl ethers, including alkyl vinyl ethers with reactive OH functionality. The backing sheet can include a crosslinking agent mixed with the fluorocopolymer. In another embodiment, the fluorocopolymer layer comprises a copolymer of tetrafluoroethylene (TFE) and hydrocarbon olefins with reactive OH functionality. The backing sheet may further include a crosslinking agent mixed with the fluorocopolymer.

The fluorocopolymer layer of the backing sheet can be applied to the compounded thermoplastic polyolefin with or without an adhesive. Also, it can be applied as a single layer or multiple layers. In another embodiment, the fluorocopolymer includes silica, and preferably hydrophobic silica. As indicated above, the outer weatherable layer is preferably coated as a solventless cure. Solubilization of solid fluoropolymer resins (e.g., Lumiflon, Zeffle, and Arkema 9301) in appropriate monomers/reactive diluents is accomplished in various liquid monomers or reactive diluents using a wide range of conventional mixing processes at room temperature. These monomers include, but are not limited to, acrylates, methacrylates, vinyl ethers, vinyl esters, vinyl halides, epoxides, vinylidene halides, alpha-olefins, and acrylonitrile. The resultant fluoropolymer resin solution may then be applied to the appropriate substrate—e.g., a polyolefin film—using conventional wet-applied coating methods. The liquid phase is then “cured”, or polymerized in-situ, via exposure to high intensity radiation—e.g., UV—or electron beam—and/or, heat to yield an interpenetrating network of the existing fluoropolymer resin and the in-situ polymerized polymer.

Selection of the appropriate monomers/reactive diluents for the fluoropolymer resins allows for controlled network, or cross-linking, formation via multiple reaction mechanisms: UV- or electron beam initiated free-radical polymerization/co-polymerization (for example) acrylic and vinyl-ether functionalities; UV- or electron beam initiated cationic polymerization/co-polymerization of (for example) vinyl-ether and epoxy functionalities; and, thermally driven cross-linking via urethane, urea, or epoxide formation.

Solventless cure of the solid fluoropolymer resins has a number of benefits. Among these benefits include the elimination of solvent usage resulting in an environmentally friendlier product. Curing can be performed at lower temperatures, thereby permitting higher line-speeds. Also, the process expands product performance capabilities by utilization of a broader range of co-polymeric candidates: acrylics, vinyl-ethers, other vinyl resins, epoxies, etc.

Solventless curing can enhance the mechanical and other properties of the resulting laminate. Solventless curing can yield interpenetrating polymeric networks (IPNs), Solventless curing of the monomer system in the presence of the fluoropolymer resin will yield an IPN or semi-IPN which as used herein refer to materials consisting of two polymers, each of which is cross-linked (or net-worked). The polymers must be cross-linked in the presence of one another and not exhibit gross phase separation upon cross-linking (if they separate, a course blend of two separate materials that generally has unsatisfactory properties due to poor interfaces between the phases results).

A benefit to such a process is that it takes advantage of the unique properties of dissimilar polymeric materials in a single coating by eliminating the use of organic solvent for deposition. IPNs and semi-IPNs can permit synergistic combination of dissimilar polymeric material due to molecular level blending prior to cross-linking/curing. For example, one benefit is to enhance thermal cycling performance by generation of an IPN between a high Tg (Lumiflon based for example) and a matrix of lower Tg material, for example polyvinylbutyl ether, polyethyl acrylate, various Tg-tailored acrylate copolymers, α-olefin copolymers.

In one embodiment of the three layer laminate of the invention, the inner layer possesses the properties of the substrate (middle layer of compounded thermoplastic polyolefin or EVA), but will also possess necessary adhesion properties to conventional encapsulants. In most instances, the inner layer would likely be comprised of a compounded polyolefin that is different in composition from the middle layer and could be co-extruded simultaneously with the base film. Alternatively, the inner layer could be applied in a subsequent coating/extrusion process.

The inner layer, however, need not be comprised of a polyolefin and can be made be made of one or more polymers of a different type. In one example, inner layer is made of compounded ethylene vinyl acetate (EVA). The vinyl acetate content of the EVA is generally about from 2 to 33 weight percent and preferably from 2 to 8 weight percent. Preferably, the inner layer provides a high level of reflectivity. This reflectivity can be provided with pigments or a coating of light reflecting material.

The pigment can be any type but white pigment is used in one preferred embodiment and can be selected from those typically used for white pigmentation, including titanium dioxide (TiO₂) and barium sulfate (BaSO₄). Of these, titanium dioxide is preferred for its ready availability. Such pigmentation can also include mica or a component that adds pearlescence. The white pigment facilitates the lamination process, providing pathways for the gas generated in the course of lamination to escape. In addition, the white pigment results in increased optical density and reflectivity of the laminate. This, in turn, increases the power generation of photovoltaic cells for which the laminate is used for a protective layer. This layer can be compounded, for example, with light stabilizers, antioxidants or both.

The specific means of forming the laminates of the present invention will vary according to the composition of the layers and the desired properties of the resulting laminate, as well as the end use of the laminate.

The layers may be applied as described above as a solventless coating as appropriate. Alternatively, the layers may be bonded together by applying an adhesive to one layer and attaching another layer, and repeating the process as necessary, depending on the number of layers. Various adhesives can be used to fabricate the laminates of the present invention, including those presently known and used for adhering layers of other laminates together. The particular adhesive that can be used will vary according to the composition of the layers and the intended use of the laminate.

The disclosures of various publications, patents and patent applications that are cited herein are incorporated by reference in their entireties.

### EXAMPLES

Laminates incorporating metalized PP (polypropylene) were prepared and tested for Moisture Vapor Transmission Rates. Metalized PP is a metalized (layer of aluminum) polypropylene. Samples were prepared using different grades commercially available from ExxonMobil: 18XM882 and 4OUBM-E5. Samples of the metalized PP and laminates of Protekt/metalized PP/EVA were subjected to MVTR testing at Southern Mississippi University. The laminates had a Protekt® (Lumiflon® based fluorocopolymer coating) layer that is 13 μm thick and an EVA (ethylene vinyl acetate) layer that is 100 μm thick. The manufacturer (ExxonMobil) reports MVTR as 0.02 g/m²/day. The laminates, however, exhibited MVTR 10 times lower as illustrated in Table 1 below in which SL081809-1 and 2 are different samples of the laminate.

TABLE 1

| Sample | WVTR: g/m²/day |
|---|---|
| SL081809-1 | 0.0014 |
| SL081809-2 | 0.0026 |
| 18XM882 | 0.0262 |
| 40UBM-E5 | 0.0240 |

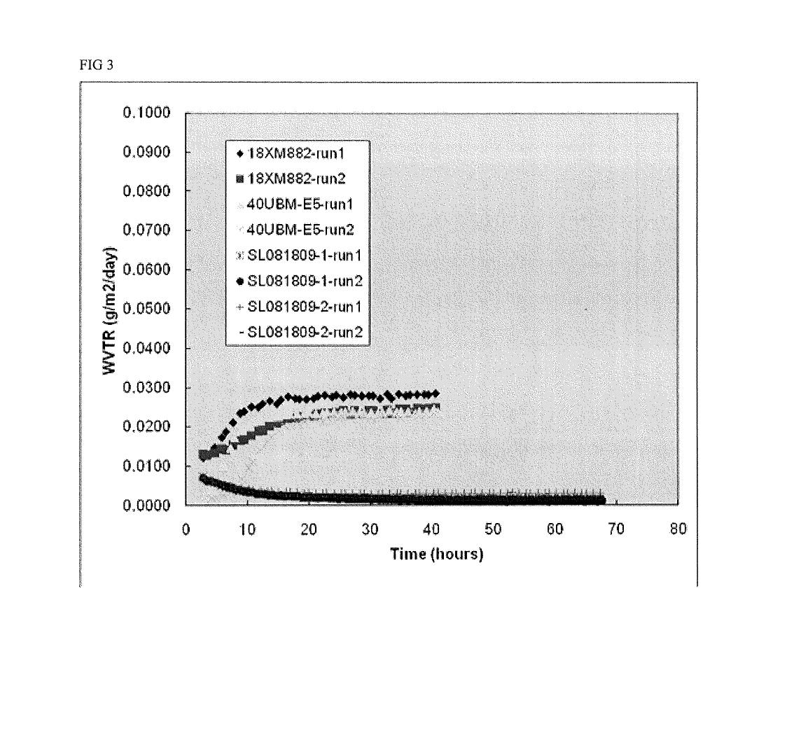

The results over time are displayed in FIG. 3.

Since MVTR is typically a function of thickness it was suspected that 100 μm EVA was the reason for the decrease in MVTR. To better understand the contribution of Protekt layer, samples of metalized PP coated with Protekt (no EVA) were tested. Additional samples were prepared and tested and which showed that Protekt coating is a reason for significant MVTR reduction. Samples of Protekt® 13 μm/4OUBM-E5 and Protekt® 13 μm/18XM88 were prepared and tested. The results were similar to that obtained for the three layer laminates in table 1. The two layer laminates had about 10 times lower MVTR. For thin films applications, where MVTR is required to be 1×10⁻³ g/m²/day, and 1×10⁻² is not enough, traditionally only sputtered films (which are expensive) or aluminum (which is metal and requires thicker surrounding polymer layers to achieve required electrical insulation) can typically be used. However, these results illustrate that with an inexpensive metalized PP with Protekt® coating on the top, the required level of moisture protection can be achieved.

### Example 2

The disadvantage of EVA and other polyolefins is their susceptibility to thermal oxidative degradation. It is especially important for polymeric materials used in PV applications as backsheets. UL 1703 states, RTI (Relative Thermal Index) of backsheet shall be at least 90° C. In addition, the RTI shall not be less than 20° C. above the measured operating temperature of the module. As modules work at higher and higher temperatures, the RTI of 105 C a common rating. When polymer degrades, the products of degradation evolve (outgas) and these products can be detected (quantitatively and qualitatively) by Head Space Gas Chromatograph (HSGC).

A number of compounded EVA samples were prepared and tested for outgas. The specific products of degradation were not identified but the quantity of volatile material evolving from the polymers after being heated at 155 C for 160-500 hrs was analyzed. Mylar A (a polyester) served as a control. Uncompounded EVA, (EVA without any additives) was also used as a control.

The samples were prepared with a number of different additives such as Uvitex OB (fluorescent optical brightener), Cyasorb UV 1164 UVA (ultraviolet light absorber), Cyanox 2777 antioxidant, Cyasorb UV 6408 light stabilizer, Cyasorb UV 2908 light stabilizer, and combinations of these additives.

The samples were prepared as follows. EVA first was dissolved upon heating and stirring in MEK at a solids content 18.7%. Each additive was dissolved in MEK at a concentration 1% and added to EVA solution in a liquid form. The prepared formulations were then coated on Mylar A 5 mil with rod #50. Coatings were heated for 20 min at 75° C. to evaporate the solvent. Then they were cut to 4 square inch samples, placed in the GC vials and capped. Samples were placed into the oven at 155 C for 160 hrs. HSGC was run on samples after 160 hrs in the oven. The results were as follows. Initial “outgassing” of all materials was negligible (approx. 400000 ng/4 sq inches). After being exposed to 155 C for a period of 160 hrs in sealed vials, the “outgassing” of “compounded” EVA remained about the same as an unheated, while the noncompounded EVA outgases about 15000000 ng/4 sq inch of volatiles. This demonstrates the process of thermal decomposition is inhibited significantly by compounding the EVA making it much more usable by itself in a backsheet eliminating the need for a polyester layer.

### Example 3

The increase in robustness of compounded EVA with respect to i) thermal stability; ii) UV stability is illustrated in the following Examples. The Example films were prepared and evaluated as follows: 1) Control-EVA-2) EVA compounded with R105 TiO₂ (DuPont), Cytec Cyasorb® UV—2908 light stabilizer (free radical scavenger hindered benzoate) 0.1% by weight, Cytec Cyanox® 2777 antioxidant 0.1% and R105 TiO₂, UVOB Ciba 0.1% by weight. The formulated EVA as described herein can be produced as a film by extrusion, blowing or other means, or can be extruded directly on the substrate, such as, polyolefin, polycarbonate, etc. Laminates were prepared as follows: 1) fluorocopolymer coating (Lumiflon® based)/5 mil Mylar A/EVA 2) fluorocopolymer/5 mil Mylar A/EVA 0.1% additives.

Testing Methods and Results:

The samples were put through a number of tests to evaluate the properties of the samples.

Oxygen Induction Time (OIT) Test

Is a technique for evaluating the oxidative stability and/or degradation of polymers. It is especially effective in examining the relative utility of antioxidants on the stability of oxidizable polymers. It is also useful in determining whether or not antioxidants have been leached from the polymer, thus negating their effectiveness. The test was performed using DSC Q200 (TA Instruments) equipped with Refrigerated Cooling System, The sample (2-3 mg) is heated in the open (no cover) aluminum pan in nitrogen atmosphere from 50° C. to 200° C. Sample is held at 200° C. for 5 min. Then the gas is changed to oxygen, and the material is continued to be held at 200° C. in oxygen atmosphere for 100 min. OIT can be used for quick screening of thermal stability EVA and efficacy of the additives.

The results obtained were that the EVA control (no additives) starts oxidizing in the oxygen atmosphere at 200° C. after 10 min of exposure. On the other hand, EVA with additives oxidized after 50 min of the testing. These results indicate that EVA with additives is thermally more stable.

UV Exposure.

Samples were exposed to UV with periodic spraying with DI water (according to UL 746C) by being held in the weather meter Xenon CI-4000 (Atlas). Color, film integrity are evaluated every 100 hrs. Tensile strength is measured initially and at the end of the test. In order to pass the test the material must maintain at least 70% of the initial property.

The results were as follows. The Control developed cracks after 700 hrs of exposure. Compounded EVA passed 1600 hrs of direct UV exposure, without cracking and maintaining 70% of initial tensile strength. These results illustrate that compounded EVA is much more UV stable than non-compounded EVA. This is extremely important for solar cells which are exposed to sunlight continually. UL 746 C requires that the parts of solar module directly exposed to sunlight must pass 1000 hrs test. Compounded EVA easily meets this requirement.

### Example 4

Compounded polypropylene based backsheet samples were subjected to cross-hatch adhesion vs. damp-heat exposure. The cross-hatch adhesion value remained constant (about 5) over 2000 hrs in damp heat. Compounded polypropylene based backsheet samples were also subjected to damp heat to test the tensile strength over time. The tensile strength remained constant over 2000 hrs.

There will be various modifications, adjustments, and applications of the disclosed invention that will be apparent to those of skill in the art, and the present application is intended to cover such embodiments. Although the present invention has been described in the context of certain preferred embodiments, it is intended that the full scope of these be measured by reference to the scope of the following claims.

The disclosures of various publications, patents and patent applications that are cited herein are incorporated by reference in their entireties.

What is claimed is:

1. A flexible backing sheet for a photovoltaic module, the backing sheet comprising:
a weatherable outer layer comprising a polyolefin;
an inner layer comprising a polyolefin; and
at least one mid-layer comprising a polyolefin, the mid-layer having a different composition from the inner layer and adhering the outer layer to the inner layer.

2. The backing sheet of claim 1 wherein the outer layer, the inner layer and the mid-layer comprise a homopolymer.

3. The backing sheet of claim 1 wherein each layer comprises polypropylene.

4. The backing sheet of claim 1 wherein the backing sheet excludes a polyester layer.

5. The backing sheet of claim 3 wherein at least one of the layers is compounded with at least one of: an antioxidant, an ultraviolet absorber, a thermally conductive filler, and a light stabilizer.

6. The backing sheet of claim 1 wherein at least two of the layers are co-extruded.

7. The backing sheet of claim 1 consisting of three layers.

8. A backing sheet for a photovoltaic module comprising solar cells, the backing sheet comprising:
an inner layer being closest to the solar cells and comprising a compounded polyolefin;
an outer layer comprising a compounded polyolefin; and
a mid-layer being adjacent to the outer layer and the inner layer, the mid-layer comprising a compounded polyolefin.

9. The backing sheet of claim 8 wherein at least one of the outer layer, the inner layer and the mid-layer comprises a compounded polypropylene.

10. The backing sheet of claim 9 wherein the polypropylene is compounded with at least one of: an antioxidant, an ultraviolet absorber, a thermally conductive filler, or a light stabilizer.

11. The backing sheet of claim 8 wherein the outer layer, inner layer and mid-layer consist essentially of polypropylene.

12. A photovoltaic module comprising:
photovoltaic cells; and
a backing sheet comprising an outer layer, an inner layer and a mid-layer adhered to both the outer layer and the inner layer, the outer layer comprising a polyolefin, the mid-layer comprising a polyolefin and the inner layer comprising a polyolefin.

13. The photovoltaic module of claim 12 wherein the polyolefin of at least one of the inner layer, the mid-layer and the outer layer is a polypropylene.

14. The photovoltaic module of claim 13 wherein at least one of the outer layer, mid-layer and inner layer is compounded with at least one of: an antioxidant, an ultraviolet absorber, a thermally conductive filler, and a light stabilizer.

15. The photovoltaic module of claim 12 wherein the photovoltaic cells are encapsulated with EVA.

16. The photovoltaic module of claim 12 wherein each of the inner layer, the mid-layer and outer layer comprises polypropylene.

17. The photovoltaic module of claim 12 wherein at least two of the inner layer, the mid-layer and the outer layer are co-extruded.
